(19) United States
(12) Patent Application Publication
(10) Pub. No.: US 2010/0090685 A1
(43) Pub. Date: Apr. 15, 2010

(54) WIDE-RANGE OPEN-LOOP CURRENT SENSOR

(76) Inventors: Olivier Andrieu, Beynost (FR); Raphael Monavon, Villeurbanne (FR); Lalao-Harijaona Rakotoarison, Belignaeux (FR)

Correspondence Address: CLARK & BRODY, 1090 VERMONT AVENUE, NW, SUITE 250, WASHINGTON, DC, 20005, US

(21) Appl. No.: 12/557,817

(22) Filed: Sep. 11, 2009

Related U.S. Application Data
(60) Provisional application No. 61/213,074, filed on May 5, 2009.

(30) Foreign Application Priority Data
Sep. 12, 2008 (FR) 08 56150

(51) Int. Cl. G01R 15/18

(52) U.S. Cl. 324/117 R

(57) ABSTRACT

The invention concerns an open-loop current sensor (1) comprising a mount casing (2) in which a magnetic circuit (3) is arranged comprising a magnetic core (5) and a measuring air gap (8), a magnetic field detector (4) being positioned in the measuring air gap (8) to measure the magnetic field induced by the electric current circulating in a cable passing through the magnetic circuit (3).

The sensor (1) also comprises connection systems (18) between the casing (2) and the terminal parts (6) of the magnetic circuit (3) to maintain a constant width of the measuring air gap.

The present invention concerns the general technical area of current sensors, and more particularly the area of open-loop current sensors.

Usually, said sensor comprises a casing in which a magnetic circuit is arranged comprising a toroidal magnetic core and an air gap, together with a magnetic field detector having a Hall-effect detection cell arranged in the air gap. This type of sensor is routinely used in automotive vehicles, for example to measure the current delivered by a battery. In this type of sensor, expansion of the magnetic core in relation to temperature causes a change in the opening of the magnetic circuit, and hence a change in the width of the air gap. On this account, accuracy of current measurement decreases as and when the temperature rises.

Document WO 2004/077078 describes a current sensor intended to overcome this problem. This sensor further comprises a strap in magnetic material welded to the magnetic core either side of the air gap. However, this solution has the drawback of requiring the fixing of an additional part to maintain the geometry of the air gap. In addition, the welding of this additional part causes partial demagnetization of the magnetic core at the weld point. This demagnetization may globally be absorbed at the cost of heat treatment after welding, but this has a negative impact on cost price. Also, this strap hinders assembly of the magnetic field detector insofar as it is positioned at the measuring air gap.

A first subject of the invention sets out to remedy the disadvantages of the state of the art by proposing a simple, low-cost, open-loop current sensor, which offers accurate current measurement over a wide range of operating temperatures.

To achieve this objective, the invention proposes an electric current sensor comprising a casing for mounting the current sensor, a magnetic circuit comprising a magnetic core containing at least two terminal parts which have two facing ends to delimit a measuring air gap, and a magnetic field detector containing a detection cell arranged in the measuring air gap to measure the magnetic field induced by the electric current circulating in a cable passing through the magnetic circuit. According to this subject of the invention, the current sensor comprises at least one connection system between each terminal part of the magnetic core and the casing, to maintain a substantially constant width of the measuring air gap so as to ensure a draw-near/draw-apart connection between the terminal parts.

Additionally, a current sensor according to the invention may also have at least one of the following additional characteristics:
at least one connection system between a terminal part of the magnetic core and the casing comprises male connecting members and female connecting members, respectively arranged on the terminal part of the magnetic core and on the casing, or conversely,
the male and female connecting members are of substantially matching shape,
the male connecting members consist of at least one projection, pin or lug, whilst the female connecting members consist of at least one housing, cavity or reservation,
the male connecting members have at least one substantially triangular cross-section, and the female connecting members have at least one cross-section matching the cross-section of the male member,
the sensor comprises positioning means between the magnetic core and the casing intended, together with the connecting system(s), to ensure positioning of the magnetic circuit relative to the casing,
the positioning means are formed at least by the connection system(s),
the casing is made in a material having low thermal expansion, preferably a glass-fibre reinforced polyamide.

Also, the current sensor described in document WO 2004/077078 has another drawback related to the use of open-loop technology. Typically the maximum intensity which can be measured by this type of sensor is in the order of 100 A in automobile applications, having regard to the permissible volume of the sensor and hence the permissible dimensions of the magnetic core. On and after this value, saturation phenomena of the magnetic core occur, leading to non-linearity of measurement.

A second subject of the invention therefore sets out to overcome the drawbacks of the prior art, by proposing a current sensor provided with an extended range of current measurement.

To achieve this objective, the invention proposes an electric current sensor comprising a casing to mount the current sensor, a magnetic circuit comprising a magnetic core containing at least two terminal parts which have two facing ends to delimit a measuring air gap, and a magnetic field detector comprising a detection cell arranged in the measuring air gap. According to this other subject of the invention, the magnetic circuit of the current sensor further comprises at least one secondary air gap obtained by reducing the cross-section of the magnetic core by between 10% and 90% of the mean cross-section So of the magnetic core, so that the magnetic induction measured by the detector varies linearly according to a first coefficient for a first so-called low current range, and also varies linearly according to a second coefficient for a second so-called strong current range, consecutive to the first current range, the second coefficient being lower than the first coefficient.

Evidently, said secondary air gap may be formed on a current sensor which does not conform to the first subject of the invention.

Advantageously, the secondary air gap(s) allow a significant increase in the sensor measuring range, which may for example be increased to 300 A with a secondary air gap in addition to the measuring air gap.

Additionally, a current sensor according to the second subject of the invention may also have at least one of the following additional characteristics:
each secondary air gap is formed of a partial slot, a through-hole or a blind hole,
the measuring air gap and the secondary air gap(s) are distributed substantially regularly over the magnetic core.

Various other characteristics will become apparent from the description below given with reference to the appended drawings which, as non-limiting examples, illustrate embodiments of the subject of the invention.

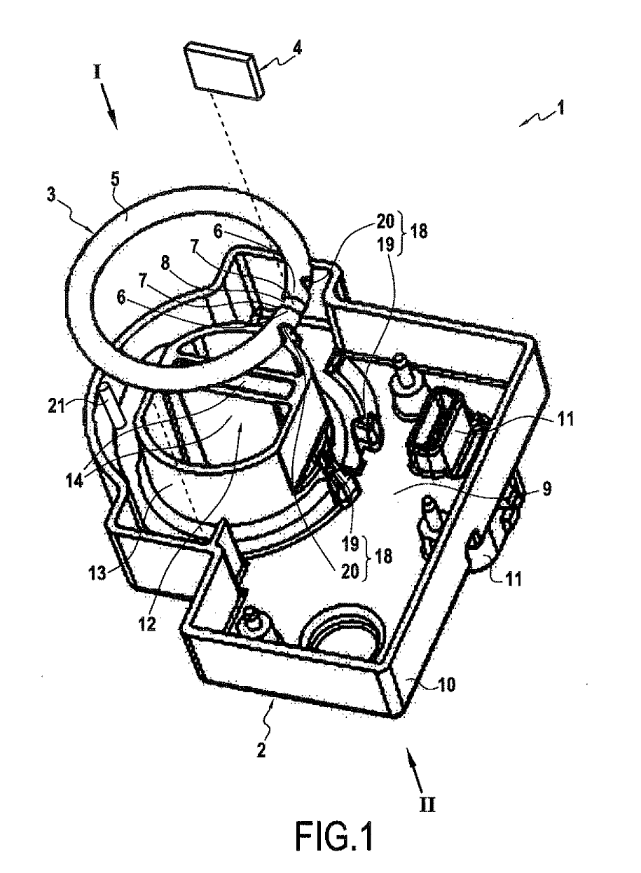

FIG. 1 is an exploded view of a current sensor according to the first subject of the invention, as seen in a direction I.

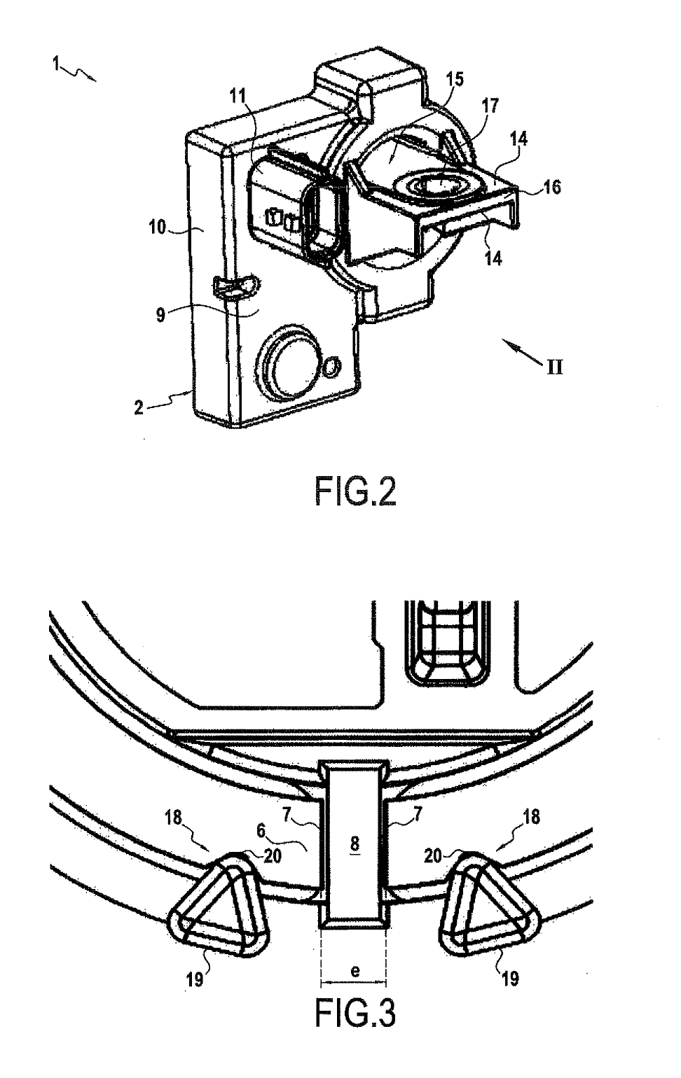

FIG. 2 is a view of the sensor in FIG. 1 as seen in direction II opposite to direction I.

FIG. 3 is a partial overhead view of the sensor in FIG. 1.

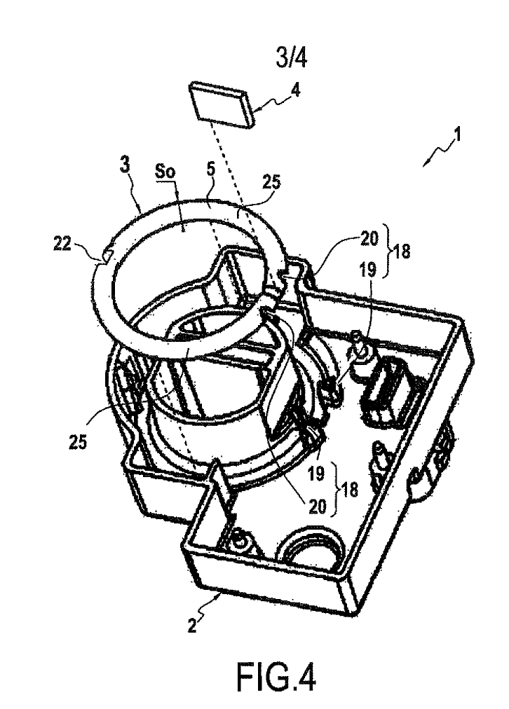

FIG. 4 is an exploded view of a current sensor according to the second subject of the invention, as seen in direction I.

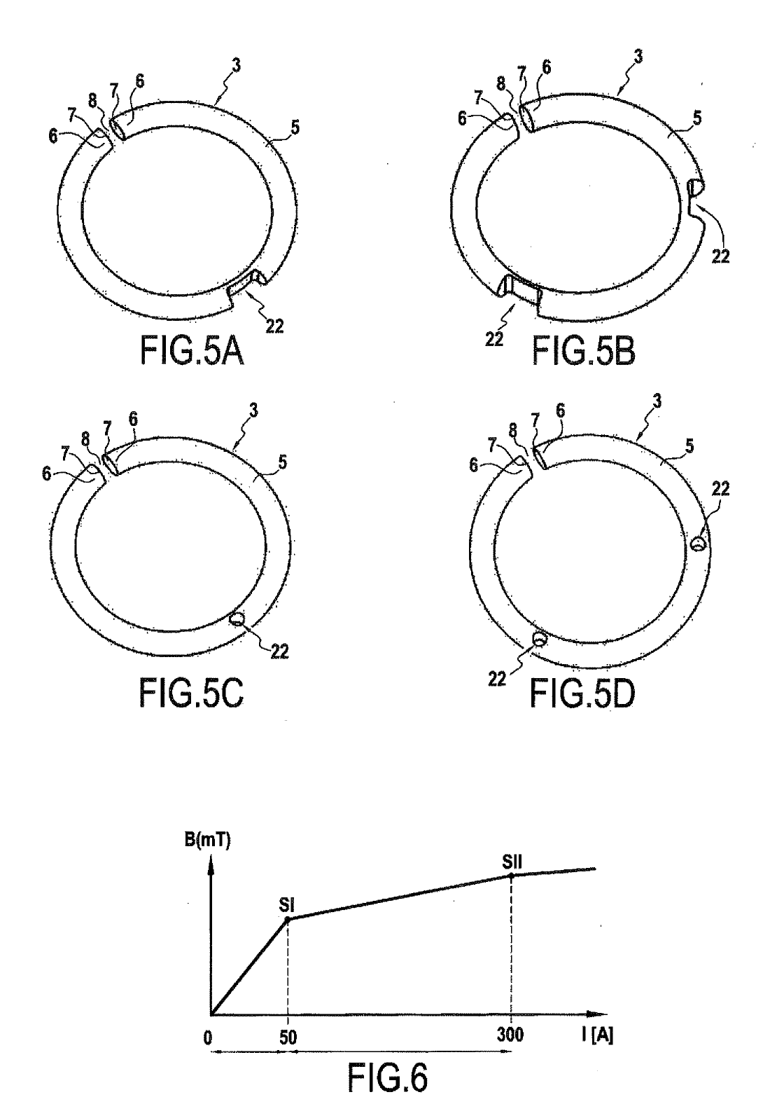

FIGS. 5A to 5D show several variants of magnetic circuits of a current sensor according to the second subject of the invention.

FIG. 6 is a graph giving the magnetic induction in the measuring air gap of a current sensor whose magnetic core comprises a secondary air gap consisting of a partial slot.

FIGS. 1 and 2 illustrate an example of a current sensor 1 according to the first subject of the invention. In this embodiment, the current sensor 1 is intended to measure the current passing through a supply cable, not shown, of an automobile battery, so as to supply information to a battery control and management system in particular.

This current sensor 1 comprises a casing 2 in which a magnetic circuit 3 and a magnetic field detector 4 are arranged.

The magnetic circuit 3 is looped so as to allow circulation of a magnetic field therein. It comprises a magnetic core 5 containing at least two terminal parts 6 which have two opposite-facing ends or transverse faces 7 to delimit a measuring air gap 8. The width e of the measuring air gap (FIG. 3) is defined as the mean distance between the two ends 7.

In the example of embodiment, the magnetic core 5 is in the form of an open toroid with circular cross-section and having a generatrix axis. Advantageously, this allows manufacturing costs to be minimized by allowing the magnetic core 5 to be made from a shaped bar.

Evidently, the magnetic core 5 may have other geometric configurations. For example, the magnetic core 5 may be of substantially circular, rectangular or oval shape. Similarly, it may have a substantially circular or rectangular cross-section for example. Also, the magnetic core 5 may be in a single part or it may consist of at two least portions which may or may not be contiguous. Accordingly, the magnetic core 5 may be obtained by forming, by machining or by sheet-metal stacking.

Also, the magnetic core 5 is made in a magnetically mild material with very low coercive field. For example, the magnetic core 5 may be made in an FeNi alloy, since this material is a good conductor of magnetic flux, which increases immunity to outside field disturbances and reduces the hysteresis of the sensor.

The magnetic field detector 4 comprises at least one measuring cell, for example a Hall-effect measuring cell, arranged in the measuring air gap 8 and linked to processing means. The detector 4 therefore measures the magnetic field induced by the electric current to be measured.

The casing 2 comprises a bottom part 9 delimited by side walls 10 rising substantially at right angles to the bottom part 9. As is conventional, it is considered that the inner side is the side of the bottom part 9 on which the side walls 10 rise, the outer side being the opposite side.

The casing 2 comprises electric connection means 11 located either side of the bottom part 9, said electric connection means 11 being intended to cooperate by assembly with a connector, not shown, linked to the battery control and management system. Once the connector has been assembled to the electric connection means 11, it is also electrically connected to the processing means of the magnetic field detector 4 via any usual means known to those skilled in the art.

The casing 2 also comprises a through orifice 12 arranged in the bottom part 9 and delimited by a skirt 13 which rises substantially at right angles to the inner side and from the bottom part 9.

In this example of embodiment, the orifice 12 is compartmented by two radial walls 14 which delimit a bracket 15 projecting either side from the orifice 12. The bracket 15 extends from the inner side as far as the free edge of the skirt, and from the outer side as far as a bracket edge 16. The bracket 15 also comprises a through bore-hole 17 located in the vicinity of the bracket edge 16.

The supply cable is provided with a flat tongue intended to be connected to the battery and provided with a bore-hole at its end. This tongue is intended to pass through the orifice 12, so that the sensor can measure the current passing through the flat tongue and hence the supply cable. Therefore, the detector 4 measures the magnetic field induced by the electric current circulating in the supply cable passing through the magnetic circuit 3. At least one radial wall 14 is intended to guide the tongue of the supply cable in translation through the current sensor 1 and to position it so that the bore-hole of the flat tongue substantially coincides with the through bore-hole 17. Advantageously, the tongue of the supply cable and the current sensor 1 may therefore be attached simultaneously onto a battery terminal plate, which allows stable positioning that is little sensitive to vibrations of the supply cable and of the sensor relative to the battery.

According to the invention, the current sensor 1 comprises at least one connection system 18 between each terminal part 6 of the magnetic core 5 and the casing 2. The purpose of this or these connection system(s) 18 is to ensure a draw-near/draw-apart connection between the terminal parts, and thereby to maintain a substantially constant width of the measuring air gap, irrespective of the thermal expansion of magnetic core 5. Advantageously, the measurement of the inductance of the magnetic core 5 by the measuring cell of the magnetic field detector 4 is therefore not dependent upon the thermal expansion of the magnetic core 5. This allows current measurement to be obtained that is substantially temperature-independent.

Advantageously, each connection system 18 is formed on each terminal part 6 in the vicinity of its delimiting transverse face 7. Having regard to the narrow width e of the measuring air gap, the connection systems 18 are located in the vicinity of each other and either side of the transverse faces 7.

For example, and in non-limiting manner, at least one connection system 18, between each terminal part 6 and the casing 2, may comprise male 19 and female 20 connecting members, respectively arranged on each terminal part 6 of the magnetic core 5 and on the casing 2, or conversely. Said male connecting members 19 may for example consist of at least one projection, pin or lug, whilst the female connecting members 20 may for example consist of a housing, a cavity or a reservation. In this case, the male 19 and female 20 connecting members are preferably of matching shape so that they can cooperate by interlocking.

In the preferred example of embodiment shown FIG. 3, the casing 2 comprises two connecting systems 18, each consisting of a male connecting member 19 arranged on the casing 2 and of a female connecting member 20 arranged on the magnetic core 5. Each male connecting member 19 is a projection of substantially triangular shape for example, which rises substantially at right angles from the bottom part 9, whilst each female connecting member 20 is a groove which extends from the outer face of the magnetic core 6 in a direction parallel to the generatrix axis of the toroid of the magnetic core 5 and which, in the example, has a cross-section substantially matching the cross-section of said male connecting member 19.

Under these conditions, the variation in width e of the air gap due to thermal expansion is identical to the variation in distance between the male connecting members 19 caused by expansion of the casing 2, which reduces mechanical stress on the magnetic circuit 3 and limits the effect of hysteresis. By taking care to limit the distance between the male connecting members 19, uncertainty regarding current measurement remains compatible with the degree of accuracy required for measuring current on an automotive vehicle.

Evidently, the connection between each terminal part 6 and the casing 2 can be achieved using other types of connection systems 18 conforming to the first subject of the invention. For example, it is possible to achieve this connection via a connection system 18 comprising two contiguous male connecting members 19 arranged either side of the casing 2, and two non-contiguous female connecting members 20 respectively arranged on each terminal part 6. It is also possible to achieve this connection via connection systems 18 not comprising any male 19 and female 20 connecting members, for example via securing devices added to the magnetic core 5. Evidently, these examples are not of a limiting nature.

The magnetic core 5 is housed around the skirt 13 and bears upon the bottom part 9. The current sensor 1 has positioning means 21 between the magnetic core 5 and the casing 2 which advantageously, in combination with the connection system(s) 18, allow stable and reproducible positioning of the magnetic circuit 3 to be obtained relative to the casing 2. For this purpose, the positioning means 21, in combination with the connection system(s) 18, prevent movement of the magnetic core 5 relative to the casing 2.

As shown FIG. 1, the positioning means 21 may consist of at least one element on which the magnetic core 5 bears and which is placed on the casing 2 diametrically opposite the projections 19 to block the magnetic core 5. This may be a fluting, projection or lug.

Evidently, the positioning means 21 may consist of all the usual means known to persons skilled in the art, for example by contact between the skirt 13 and the magnetic core 5.

In one embodiment, the positioning means 21 consist at least of the connection system(s) 18. In this case, the connection system(s) 18 are advantageously used simultaneously to maintain a substantially constant width e of the measuring air gap and to obtain precise positioning of the magnetic circuit 3 relative to the casing 2. For this purpose, the connection between each terminal part and the casing 2 may, for example, be connection systems 18 each consisting of a pin or lug arranged on the casing 2 and of an orifice arranged on the magnetic core 5 and cooperating with the pin or lug by interlocking.

In the above example of embodiment, the bottom part 9, the side walls 10, the electric connection means 11, the bracket 15 and the male connecting members 19 are made in a single piece in injected plastic. Advantageously, a plastic is used which has a low thermal expansion coefficient e.g. glass-fibre reinforced polyimide, to minimize the thermal expansion of the casing 2, the variation in distance between the male connecting members 19 and hence the variation in width e of the measuring air gap.

Additionally, at least part of the volume delimited by the bottom part 9, the side walls 10 and the skirt 13 is intended to be filled with cast resin once the sensor has been assembled, so as to guarantee the sealing of the current sensor 1 whilst ensuring the holding in position of the different components.

FIG. 4 shows an example of a current sensor 1 according to the second subject of the invention.

In this example of embodiment, and to facilitate general understanding, only the differences between the first and second subjects of the invention will be explained below. Any non-explained characteristic is therefore assumed to be similarly produced in the example of shown embodiment FIGS. 1 to 3 and in the example of shown embodiment FIG. 4.

According to the invention, the magnetic circuit 3 further comprises at least one secondary air gap 22 which delays saturation of the current sensor and extends its measuring range. Each air gap 22 is obtained by reducing the transverse cross-section of the magnetic core 5 by between 10% and 90% of the mean transverse cross-section So of the magnetic core 5. In other words, the magnetic core 5 has at least one narrowing or reduction of material which delimits a secondary air gap 22.

FIGS. 5A to 5D show several variants of magnetic circuits 3 of a current sensor 1 according to the second subject of the invention, comprising secondary air gaps 22 made in different forms. In all these variants, the magnetic circuit 3 comprises a magnetic core 5 containing two terminal parts 6 which have two facing ends 7 to delimit a measuring air gap 8.

The secondary air gap 22 in FIG. 5A consists of a trapezoid partial slot, located opposite the measuring air gap 8 relative to the generatrix axis of the toroid of the magnetic core 5. This trapezoid partial slot has a substantially trapezoid cross-section along a plane orthogonal to the generatrix axis of the toroid forming the magnetic core 5.

In this example of embodiment, the secondary air gap 22 is positioned opposite the measuring air gap 8 relative to the generatrix axis of the toroid of the magnetic core 5.

FIG. 5B differs from FIG. 5A in that it comprises two secondary air gaps 22 each consisting of a partial trapezoidal slot of substantially trapezoid cross-section along a plane orthogonal to the generatrix axis of the toroid. The measuring air gap 8 and the two secondary air gaps 22 are equi-distributed around the circumference of the magnetic core 5.

The secondary air gap 22 in FIG. 5C consists of a hole of substantially circular cross-section along a plane orthogonal to the generatrix axis of the toroid forming the magnetic core 5, located opposite the measuring air gap 8 relative to the generatrix axis of the toroid of the magnetic core 5. This may be a through-hole or a blind hole.

FIG. 5D differs from FIG. 5C in that it comprises two secondary air gaps 22 each consisting of a through-hole or blind hole of substantially circular cross-section along a plane orthogonal to the generatrix axis of the toroid. The measuring air gap 8 and the two secondary air gaps 22 here are also equi-distributed around the circumference of the magnetic core 5.

Evidently, the partial slots may have any type of shape, and the above examples of embodiment are only of an illustrative nature.

Similarly, the partial slot may be obtained by combining a full slot and a part added to the full slot. The added part may be a spacer, e.g. a spacer in non-magnetic or magnetic material, or a projecting part of the casing adapted to be housed in the full slot after mounting the current sensor 1.

FIG. 6 is a graph showing the magnetic inductance B of the magnetic circuit 5 in the measuring air gap 8, along the Y-axis, in relation to the current intensity circulating in the supply cable, along the X-axis, for a current sensor 1 comprising a magnetic circuit 3 according to FIG. 5A.

It is observed that with low intensities, the magnetic induction increases rapidly with the measured current, this phenomenon being due to the partial slot. The absence of any offset is also observed, which denotes low sensitivity of the sensor to outside magnetic fields. In the absence of a secondary air gap 22, said outside magnetic fields lead to the occurrence of an offset depending on the orientation of the sensor 1 relative to the said magnetic fields. This phenomenon leads to substantial loss of accuracy when measuring low currents, e.g. less than 5 A.

The magnetic material of the secondary air gap 22 is the first region to be saturated, through its smaller cross-section than the remainder of the magnetic core 5. This saturation of the secondary air gap 22 depends on the ratio between the cross-section of the partial slot and the mean cross-section So of the magnetic core 5, and corresponds to the saturation point S_{I} in the graph. The magnetic induction measured by the detector 4 varies linear fashion according to a first coefficient for a first, so-called low current range e.g. of between 0 and 50 A.

After saturation, the secondary air gap 22 behaves as a full slot since the permeability of a saturated region can be compared to the permeability of a vacuum. On this account, the sensor has linear behaviour between the saturation point S_{I} of the secondary air gap 22 and the saturation point S_{II} of the remainder of the magnetic core 5. Magnetic induction measured by the detector 4 therefore varies linear fashion according to a second coefficient and for a second range of current taken between the saturation points S_{I}, S_{II} and for example lies between 50 and 300 A. It is to be noted that the second coefficient of linear variation is lower than the first coefficient of variation. It is to be noted that the value of the narrowing cross-section which delimits the secondary air gap 22 defines the span of the first current range.

It is to be noted that the linearity measured over a range of current is defined as the maximum difference between the induction values measured over this range and those obtained by linear interpolation on this range with a straight line which best approximates all the values. It is estimated that the measuring range is linear if this difference is less than 1% of the measured inductance value.

Therefore, the measured inductance is globally linear relative to the current to be measured over the entire measuring range, with a break in slope corresponding to saturation point S_{I} of the secondary air gap 22. A current sensor 1 provided with said magnetic circuit 3, associated with an electronic signal processing circuit, therefore simultaneously benefits from good accuracy at low intensities e.g. less than 50 A, and from an extended measuring range e.g. from 0 to 300 A.

By making the secondary air gap(s) 22 in the form of a narrowing of the cross-section of the magnetic core 5, it is therefore possible to reduce substantially the sensitivity to outside magnetic fields whilst maintaining the benefit of an increased measuring range.

The invention is not limited to the described, illustrated examples, since various modifications may be made thereto without departing from the scope of the invention.

1- Electric current sensor (1) comprising:
a casing (2) to mount the current sensor (1),
a magnetic circuit (3) comprising a magnetic core (5) comprising at least two terminal parts (6) which have two facing ends (7) to delimit a measuring air gap (8) and
a magnetic field detector (4) comprising a detection cell arranged in the measuring air gap (8), to measure the magnetic field induced by the electric current circulating in a cable passing through the magnetic circuit (3),
characterized in that it comprises at least one connection system (18) between each terminal part (6) of the magnetic core (5) and the casing (2) to maintain a substantially constant width e of the measuring air gap (8) so as to ensure a draw-near/draw-apart connection between the terminal parts (6).

2- Electric current sensor according to claim 1, characterized in that at least one connection system (18) between a terminal part (6) of the magnetic core (5) and the casing (2) comprises male connecting members (19) and female connecting members (20), respectively arranged on the terminal part (6) of the magnetic core (5) and on the casing (2), or conversely.

3- Electric current sensor according to claim 2, characterized in that the male (19) and female (20) connecting members are of substantially matching shape.

4- Electric current sensor according to claim 2, characterized in that the male connecting members (19) consist of at least one projection, pin or lug, whilst the female connecting members (20) consist of at least one housing, cavity or reservation.

5- Electric current sensor according to claim 2, characterized in that the male connecting members (19) have at least one substantially triangular cross-section, and in that the female connecting members (20) have at least one cross-section matching the male member cross-section.

6- Current sensor according to claim 1, characterized in that it comprises positioning means (21) between the magnetic core (5) and the casing (2) so that, in combination with the connection system(s) (18), it can ensure positioning of the magnetic circuit (3) relative to the casing (2).

7- Electric current sensor according to claim 6, characterized in that the positioning means (21) are at least formed by the connection system(s) (18).

8- Current sensor according to claim 1, characterized in that the casing (2) is made in a material having low thermal expansion, preferably glass-fibre reinforced polyamide.

9- Current sensor according to claim 1, characterized in that the magnetic circuit (3) comprises at least one secondary air gap (22) obtained by a reduction in the cross-section of the magnetic core (5) of between . . . % and . . . % of the mean cross section So of the magnetic core (5) so that the magnetic induction measured by the detector (4) varies linearly according to a first coefficient for a first so-called low current range, and also varies linearly according to a second coefficient for a second so-called strong current range, consecutive to the first current range, the second coefficient being lower than the first coefficient.

10- Current sensor according to claim 9, characterized in that the secondary air gap (22) is delimited by a reduction in the cross-section of the magnetic core by a chosen value defining the second coefficient of linear variation of magnetic induction, obtained by a reduction of between 10% and 80% of So of the cross-section of a portion of the magnetic core (5).

11- Current sensor according to claim 10, characterized in that each secondary air gap (22) consists of a partial slot, a through-hole or a blind hole.

12- Current sensor according to claim 9, characterized in that the measuring air gap (8) and the secondary air gap(s) (22) are distributed substantially regularly over the magnetic core (5).
